(19) United States
(12) Patent Application Publication
(10) Pub. No.: US 2020/0075548 A1
(43) Pub. Date: Mar. 5, 2020

(54) INTERCONNECTS FOR A MULTI-DIE PACKAGE

(71) Applicant: Micron Technology, Inc., Boise, ID (US)

(72) Inventors: Kang-Yong Kim, Boise, ID (US); Chan Yoo, Boise, ID (US); Dong Soon Lim, Boise, ID (US); Jaekyu Song, Taichung City (TW)

(21) Appl. No.: 16/120,991

(22) Filed: Sep. 4, 2018

(51) Int. Cl. H01L 25/065; H01L 23/00; H01L 23/498

(52) U.S. Cl. CPC H01L 25/0657; H01L 24/48; H01L 2225/06562; H01L 2225/0651; H01L 2224/48225; H01L 23/49811

(57) ABSTRACT

Systems, devices, and methods for interconnects for a multi-die package are described. A multi-die package may include a set of conductive pillars and two or more semiconductor dice that each include a bond pad. In some cases, the multi-die package may include a plurality of pillar-wire combinations, and a bond wire may couple a corresponding conductive pillar with a corresponding bond pad. Pillar-wire combinations may each collectively have a matched impedance, or pillar-wire combinations in different groups may have different collective impedances. In other cases, a conductive pillar may be directly coupled with a corresponding bond pad without a bond wire. Different pillar-wire combinations or directly-coupled pillars may carry different signals. In some cases, pillars may be individually impedance-matched to a desired impedance.

### BACKGROUND

The following relates generally to apparatuses for semiconductor packages and more specifically to interconnects for a multi-die package.

A computing system may include one or more multi-die packages that include multiple semiconductor dice. The computing system may manage information in numerous electronic devices such as computers, wireless communication devices, internet of things, cameras, digital displays, and the like. A multi-die package may include a variety of semiconductor dice. For example, a multi-die package may include memory devices, a controller managing the memory devices and interfacing with a host, or other components related to operations of the multi-die package, or some combination thereof.

Memory devices in a multi-die package may include random access memory (RAM), read only memory (ROM), dynamic RAM (DRAM), synchronous DRAM (SDRAM), ferroelectric RAM (FeRAM), magnetic RAM (MRAM), resistive RAM (RRAM), flash memory, not-AND (NAND) memory, phase change memory (PCM), and others. Memory devices may be volatile or non-volatile. Non-volatile memory cells (e.g., NAND memory cells) may maintain logic states for extended periods of time even in the absence of an external power source. Volatile memory cells (e.g., DRAM cells) may lose logic states over time unless they are periodically refreshed by an external power source.

Improving a multi-die package may include scaling a form factor, reducing power consumption, increasing a quantity of semiconductor dice, improving power delivery capability, or providing robust signals among the semiconductor dice, among other metrics.

### BRIEF DESCRIPTION OF THE DRAWINGS

FIG. 1 illustrates an example of a computing system that supports interconnects for a multi-die package in accordance with aspects disclosed herein.

FIGS. 2A and 2B, 3A and 3B, and 4A and 4B illustrate exemplary diagrams of multi-die packages that support interconnects for a multi-die package in accordance with aspects disclosed herein.

FIGS. 5 through 6 illustrate a method or methods supporting interconnects for a multi-die package in accordance with aspects disclosed herein.

### DETAILED DESCRIPTION

A multi-die package may include a quantity of semiconductor dice to provide a small footprint on a circuit board or other structure that distributes (e.g., routes) various signals to or from the semiconductor dice. The multi-die package may include multiple semiconductor dice, bond wires, and a substrate. The semiconductor dice may each include one or more bond pads, and the substrate may also include bond pads. In some cases, the multi-die package may include bond wires, and a bond wire may couple (e.g., electrically connect) a bond pad of a semiconductor die with a corresponding bond pad of the substrate. As such, a set of bond wires within a multi-die package may be regarded as a routing network (e.g., a combination of conductive signal paths) that distributes various signals (e.g., power signals, clock signals, data signals) between bond pads of the substrate and bond pads of the semiconductor dice. Such conductive signal paths may be referred to as interconnects in a multi-die package.

When two or more semiconductor dice are stacked on top of another within a multi-die package, lengths of bond wires may be different due to different heights of semiconductor dice (e.g., different distances from the substrate). As a result, bond wires may have different lengths resulting in different impedances (e.g., inductance, capacitance, or resistance, or any combination thereof) associated with different bond wires. In some cases, lengths of some bond wires may need to be extended (to reach a semiconductor die stacked farther away from the substrate) such that the extended lengths may result in an undesired increase in impedances of the bond wires.

Multi-die packages may be used to support a variety of high-speed operations for a computing system. High-speed operations may be associated with signals with high-frequencies that may increase impedances of signal paths as a function of frequency. In some cases, a multi-die package may experience issues during high-speed operations when interconnects in the multi-die package include signal paths having large impedances or signal paths exhibiting mismatched impedances, or both. For example, multi-die packages may fail to support high-speed operations (e.g., fail to meet a latency requirement to store or provide data) due to large impedances of interconnects. In some cases, the impedance of a signal path with respect to a signal may depend on the frequency of the signal—for example, a signal path with a high inductive impedance may impose a large amount of impedance for a high frequency signal, such as high-frequency noise in a power signal. In some cases, a portion of interconnects that delivers power signals between bond pads of a substrate and bond pads of semiconductor dice may be referred to as a power delivery network. Further, mismatched impedances in different signal paths of the interconnects of a multi-die package may result in undesired degradations (e.g., distortions, delays) in signals that may be transmitted on the interconnects (e.g., clock signals, data signals).

Concepts disclosed herein may support interconnects (e.g., a signal path for power signals) of a multi-die package with matched impedances (at least within an acceptable limit) via conductive pillars that may have different physical configurations (e.g., heights, cross-sectional areas). Further, the concepts may support impedance-matching among signal paths for different types or categories of signals (e.g., signal paths for power signals, for clock signals, for data signals, etc., or for any combination of signals) of the interconnects of a multi-die package to reduce degradations in signals. Thus, a multi-die package using the concepts described herein may mitigate issues associated with high-speed operations, such as power delivery network issues. These benefits are merely exemplary, and other benefits may be appreciated by those of skill in the art.

In some cases, conductive pillars (having different heights or cross-sectional areas, or both) may provide interconnects for a set of semiconductor dice in a multi-die package, where the interconnects may have a matched impedance despite different distances between a substrate (e.g., bond pads of the substrate) and different semiconductor dice (e.g., bond pads of different semiconductor dice). Impedance matching between interconnects may improve integrity of a variety of signals transmitted over the interconnects (e.g., clock signals, data signals, power signals). In some cases, impedance matching may be done to a common value (e.g., 40 ohms) within a multi-die package. In other cases, impedance matching may be done to several values (e.g., 20, 30, or 40 ohms) within a multi-die package. Different signal paths having different impedances may carry different signals (e.g., power signals, data signals, clock signals).

In some cases, the conductive pillars of the interconnects may replace some or all of a bond wire that may otherwise (e.g., conventionally) be required to reach semiconductor dice disposed some distance from the substrate. The conductive pillars may maintain a desired and configurable overall impedance of a signal path of the interconnects within an acceptable limit to provide improved impedance-matching capabilities or to avoid undesirably large impedances (e.g., inductances, resistances) associated with such extended bond wires (e.g., by having different cross-sectional areas in view of different heights of the conductive pillars, such as taller conductive pillars that are fatter, and shorter conductive pillars that are more narrow). As a result, the conductive pillars may provide an improved current flow for a signal (e.g., a power signal), such as by reducing a voltage drop along the signal path of the interconnects, for example.

In some cases, the conductive pillars may facilitate an easier manufacturing process due to a reduced height difference between the conductive pillars (disposed above bond pads of the substrate) and bond pads of a respective semiconductor die, and thus a reduced span for bond wires to form connections (e.g., loops, bridges). In some cases, the conductive pillars may support enhanced bond wire loop control (e.g., less bond wire movement, due to shorter bond wires and thus enhance bond wire rigidity), which may in turn, result in a consistent and stable bond wire quality. These benefits are again merely exemplary, and other benefits may be appreciated by those of skill in the art.

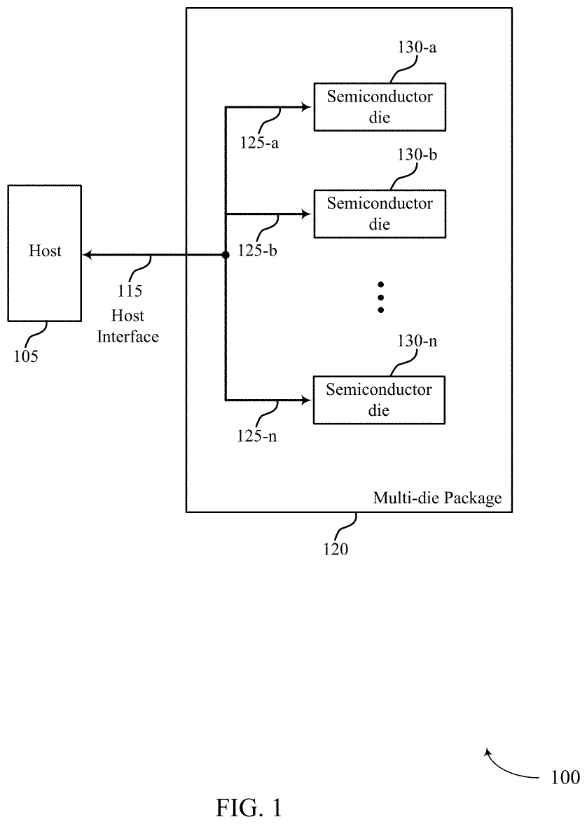

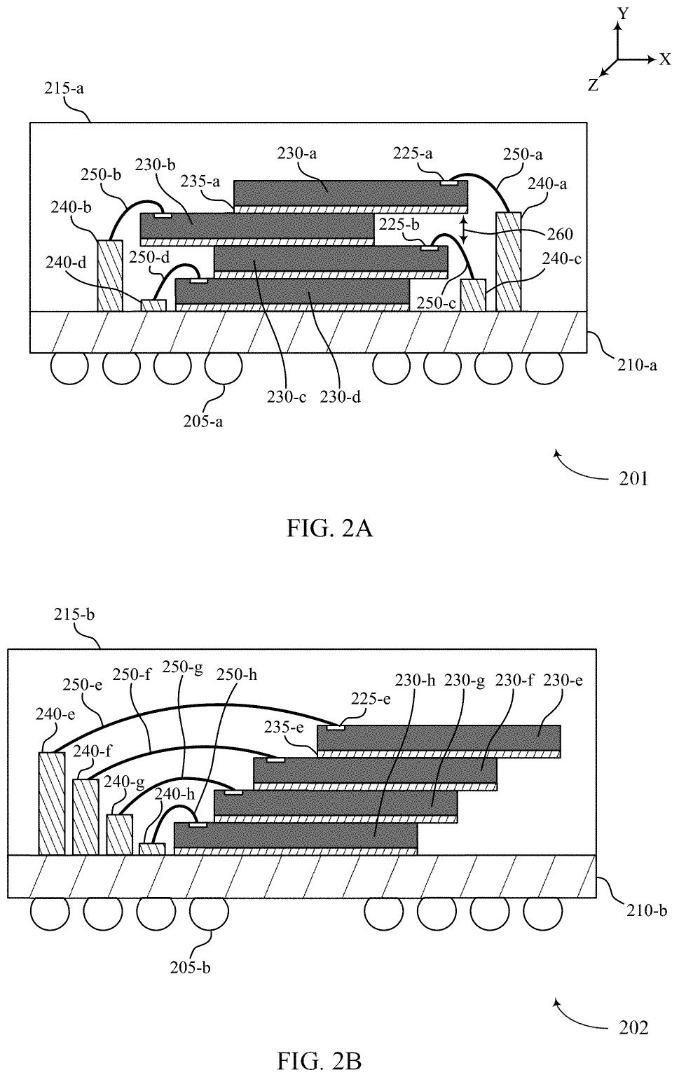

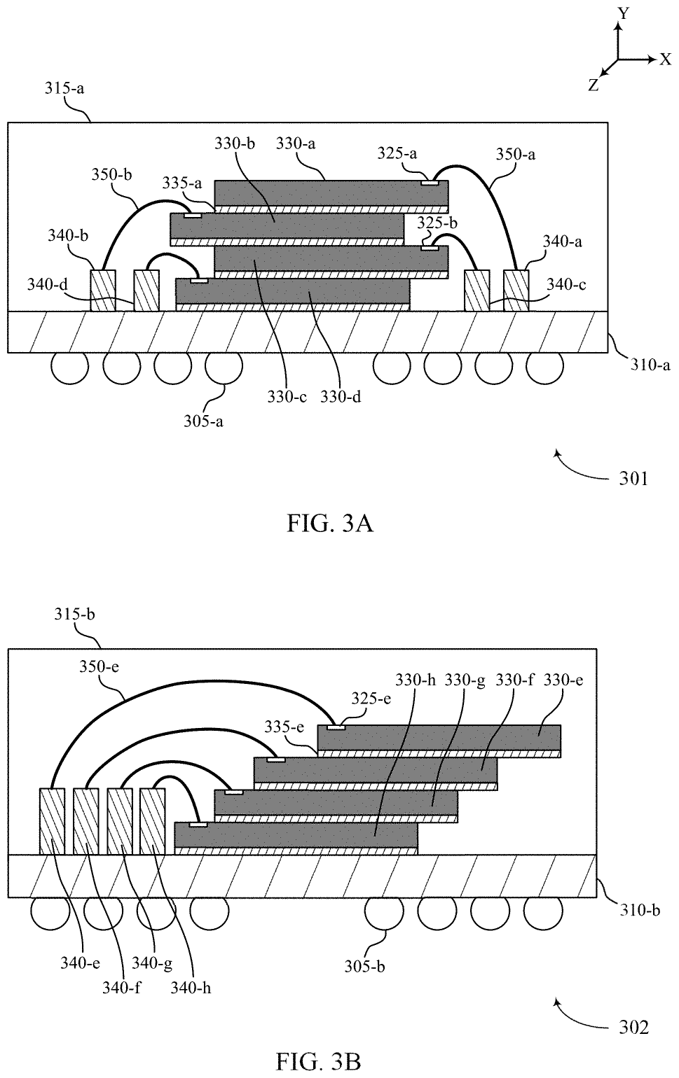

Features of the disclosure introduced herein are further described below at an exemplary system level in the context of FIG. 1. Specific examples of a multi-die package are then described in the context of FIGS. 2 through 3. These and other features of the disclosure are described by way of using illustrative examples of multi-die packages including semiconductor dice (e.g., memory devices, such as dice that each include DRAM cells). The semiconductor dice in a multi-die package may include other types of devices, such as memory devices employing different memory technologies than DRAM memory technology, such as FeRAM technology, PCM technology, MRAM technology, 3D XPoint™ memory technology, among other examples. As such, the concepts disclosed herein are not limited to memory technology or to any particular memory technology (e.g., DRAM technology).

FIG. 1 illustrates an example of a computing system 100 that supports interconnects for a multi-die package in accordance with aspects disclosed herein. The computing system 100 may include a host 105 coupled with a device 120 through a host interface 115 (which may also be referred to as a host link). The host 105 may be or include a server, a system on a chip (SoC), a central processing unit (CPU), or a graphics processing unit (GPU), among other examples. In some examples, the host 105 may access (e.g., read from, write to) one or more semiconductor dice 130 located in the device 120 through the host interface 115. In some cases, the device 120 may be or include a multi-die package.

The host interface 115 (e.g., a host link) may be compatible with or employ a protocol to support access operations between the host 105 and the one or more semiconductor dice 130. In some cases, the host interface 115 may be configured to transfer data at a data transfer rate (e.g., 4 to 8 Giga-bit per second per pin) in at least one direction (e.g., sending or receiving).

The device 120 (e.g., a device in a multi-die package) may, in some cases, be referred to as a memory device, memory system, or memory subsystem. The device 120 may include channels 125. The channels 125 may be configured to transport data between the host 105 and the multiple semiconductor dice 130. Each of the channels 125 (e.g., a channel 125-a) may comprise an aggregation of multiple channels (e.g., multiple channels having a smaller bandwidth than the channel 125-a) for transporting a variety of signals in parallel. In some cases, channels 125 may be examples of or include aspects of signal paths for transmitting (e.g., sending or receiving) a variety of signals (e.g., power signals, data signals, command signals).

The device 120 may also include multiple semiconductor dice 130 to obtain a specified or desired capacity (e.g., memory capacity) of the device 120. In some examples, one or more of the semiconductor dice 130 may include a DRAM memory array. In other examples, one or more of the semiconductor dice 130 may include other kinds of memory cells (e.g., FeRAM cells, MRAM cells, PCM cells, NAND memory cells, 3D XPoint™ memory cells).

In some cases, the device 120 may include other components, e.g., a memory controller. A controller may include various functional blocks that facilitate operations of the device 120 in conjunction with the multiple semiconductor dice 130 and the host 105. In some cases, such controller may include aspects of an interface controller to accommodate different specifications, constraints, or characteristics associated with the host interface 115 or the channels 125, or both. In some examples, such a controller may be an ASIC, a general-purpose processor, other programmable logic device, discrete hardware components (e.g., a chiplet), or it may be a combination of components. In some case, such controller may be part of the host 105.

In some cases, the host 105 (or a controller) may read data from or write data at semiconductor dice 130 (e.g., a semiconductor die 130-a) in conjunction with a local controller (e.g., local to the semiconductor die 130-a) that may perform various operations (e.g., writing data to memory cells, reading data from memory cells, transmitting control signals). In some examples, the local controller may send requested data to the host 105 (or controller) through one of the channels 125.

In some cases, a device (e.g., a device 120) may include a set of semiconductor dice disposed above a substrate, where each semiconductor die of the set may include an upper surface in contact with (e.g., that includes) a bond pad. The device 120 may also include a set of conductive pillars above the substrate. Further, the device 120 may include a set of bond wires and each bond wire of the set may couple a conductive pillar (e.g., pillars including a highly conductive material such as copper) with a corresponding bond pad (e.g., a bond pad of a semiconductor die of the set). In some cases, the set of bond wires and the set of conductive pillars may include (e.g., form) a set of pillar-wire combinations such that each pillar-wire combination may include a bond wire and a corresponding conductive pillar. In some cases, each of the pillar-wire combinations may have a matched impedance. In other cases, the set of pillar-wire combinations may include groups of pillar-wire combinations, where pillar-wire combinations in different groups of pillar-wire combinations may have different impedances. In some cases, the set of conductive pillars may include a first group of conductive pillars having a first height (or cross-sectional area) and a second group of conductive pillars having a second height (or cross-sectional area) different from the first height.

In some cases, a device (e.g., a device 120) may include a set of semiconductor dice disposed above a first region of a substrate, where each semiconductor die of the set includes a lower surface in contact with (e.g., that includes) a bond pad. The device 120 may further include a set of conductive pillars above a second region of the substrate where each conductive pillar of the set may be directly coupled with a corresponding bond pad. The second region may be a subset of the first region of the substrate, and thus the first region of the substrate may in some cases overlap with the second region of the substrate. In some cases, conductive pillars of the set may be impedance-matched to one another. Further, a first conductive pillar of the set may have a different height (or cross-sectional area) than a second conductive pillar of the set. In other cases, the set of conductive pillars may further include groups of conductive pillars, where conductive pillars in different groups may have different impedances. In some cases, each conductive pillar of the set may be electrically coupled with the corresponding bond pad via a solder, and/or may be in direct contact with the corresponding bod pad.

FIG. 2A illustrates an exemplary diagram 201 of a multi-die package that supports interconnects for a multi-die package in accordance with aspects disclosed herein. The diagram 201 may include aspects of the computing system 100 described with reference to FIG. 1. The diagram 201 illustrates an example of a stack of semiconductor dice disposed above a substrate in a multi-die package and interconnects that may couple bond pads of the semiconductor dice with bond pads of the substrate. The diagram 201 may depict a cross-sectional view captured in a plane in the z-direction (e.g., a plane in the z-direction that includes x-axis and y-axis). As such, other structures (not shown) may exist in a different plane in the z-direction. The diagram 201 provides an illustrative example of various features in accordance with aspects disclosed herein, which are not limited to this example.

The diagram 201 illustrates a set of solder balls 205 (e.g., a solder ball 205-a of the set of solder balls). In some cases, the set of solder balls 205 may be examples of or include aspects of the host interface 115 described with reference to FIG. 1. For example, a host (e.g., the host 105 described with reference to FIG. 1) may be coupled with one or more multi-die packages (e.g., the multi-die package of the diagram 201) at least in part through the set of solder balls 205. The diagram 201 also illustrates a substrate (e.g., a substrate 210-a), which may also be referred to as a package substrate. The substrate 210-a may include embedded conductive paths (e.g., traces or wires) between a solder ball of the set (e.g., the solder ball 205-a) and a corresponding bond pad of the substrate 210-a. In some cases, a bond pad of a substrate may be referred to as a substrate bond pad. Further, the diagram 201 illustrates an encapsulant (e.g., an encapsulant 215-a) that may provide a housing for a plurality of semiconductor dice 230 (e.g., semiconductor dice 230-a through 230-d), a plurality of conductive pillars 240 (e.g., conductive pillars 240-a through 240-d), and a plurality of bond wires 250 (e.g., bond wires 250-a through 250-d). The encapsulant 215-a may protect various components of a multi-die package (e.g., the multi-die packages of the diagram 201) from external environmental factors (e.g., shock, moisture, heat).

Each semiconductor die of the plurality 230 (e.g., a semiconductor die 230-a) may include one or more bond pads (e.g., a bond pad 225-a). In some cases, a surface that is furthest removed from the substrate 210-a may be referred to as an upper surface of a semiconductor die (e.g., a semiconductor die 230-a). In some cases, an upper surface of a semiconductor die 230 may include or otherwise be in contact with one or more bond pads 225 (e.g., the bond pad 225-a). In some cases, a die attach film (DAF) (e.g., DAF 235-a) may be disposed in contact with a lower surface (e.g., the opposite surface of the upper surface) of a semiconductor die (e.g., a semiconductor die 230-a). The DAF 235 may attach a semiconductor die (e.g., a semiconductor die 230-a) to another semiconductor die (e.g., a semiconductor die 230-b) or to a substrate (e.g., the substrate 210-a). As such, the upper surface (e.g., the surface in contact with a bond pad 225-a) of each semiconductor die of the plurality 230 may face away from the substrate 210-a.

A plurality of conductive pillars 240 (e.g., conductive pillars 240-a through 240-d) may be disposed above the substrate 210-a, where each conductive pillar of the plurality (e.g., a conductive pillar 240-a) may be coupled with a corresponding bond pad of the substrate (e.g., a corresponding substrate bond pad and eventually to a host through a solder ball, e.g., a solder ball 205-a). Further, a conductive pillar (e.g., a conductive pillar 240-a) may have a height corresponding to a desired separation distance between the top of the conductive pillar and a corresponding semiconductor die (e.g., a semiconductor die 230-a) of the plurality. As a result, the conductive pillar (e.g., the conductive pillar 240-a) may facilitate formation of a bond wire (e.g., a bond wire 250-a) that couples a bond pad (e.g., a bond pad 225-a) of a semiconductor die (e.g., a semiconductor die 230-a) with the corresponding conductive pillar 240 instead of having the bond wire (e.g., the bond wire 250-a) extending a greater distance that would be required to reach the corresponding bond pad of the substrate 210.

The plurality of conductive pillars 240 may include conductive materials (e.g., copper (Cu), tungsten (W), aluminum (Al), gold (Au), or other conductive materials, alloys, compounds, or the like). In some cases, one or more liner layers (e.g., titanium (Ti), titanium nitrides (TiNₓ), tantalum (Ta), tantalum nitrides (TaNₓ), or some combination thereof) may be used at an interface of the conductive pillars and other aspects of the multi-die package (e.g., an interface between a conductive pillar and a bond pad of a substrate).

Conductive pillars may have different physical shapes—e.g., heights, cross-sectional areas, cross-sectional shapes (e.g., circular, elliptical, square, rectangular, or the like). In some cases, a conductive pillar (e.g., a conductive pillar 240-c) may have a height that may be equal to (or substantially identical to) a thickness of a semiconductor die (e.g., a semiconductor die 230-d) of the plurality. Another conductive pillar (e.g., a conductive pillar 240-a) may have a height that may be greater than a thickness of a semiconductor die of the plurality, e.g., equal to some multiple of the thickness of a semiconductor die of the plurality. In some cases, a conductive pillar (e.g., a conductive pillar 240-d) may have a height that may be less (e.g., having a shorter height) than a thickness of a semiconductor die (e.g., a semiconductor die 230-d) of the plurality. In some cases, one or more conductive pillars having a shorter height than a thickness of a semiconductor die (e.g., a conductive pillar 240-d) may be omitted—e.g., a bond wire may directly connect a bond pad of a semiconductor die (e.g., a semiconductor die 230-d) and a bond pad of the substrate 210 exclusive of a conductive pillar (e.g., a conductive pillar 240-d).

In some cases, a particular physical shape of a conductive pillar may be determined based on an acceptable value of an impedance (e.g., 25 ohms) associated with the conductive pillar, which in turn may be based on a signal that the conductive pillar may carry (e.g., a power signal). In other cases, physical shapes of conductive pillars may be determined to match impedances of several conductive pillars to a particular impedance value (e.g., 40 ohms). For example, a first conductive pillar (e.g., a conductive pillar 240-c) may be short (e.g., having a less height than other conductive pillars) and thin (e.g., having a less cross-sectional area than other conductive pillars) while a second conductive pillar (e.g., a conductive pillar 240-a) may be tall (e.g., having a greater height than other conductive pillars) and thick (e.g., having a greater cross-sectional area than other conductive pillars) to accomplish a particular matched impedance (e.g., 40 ohms) for both the first conductive pillar and the second conductive pillar.

In some cases, the plurality of conductive pillars 240 may include a first group of conductive pillars (e.g., two or more conductive pillars 240-a) having a first height and a second group of conductive pillars (e.g., two or more conductive pillars 240-b, two or more conductive pillars 240-c, two or more conductive pillars 240-d) having a second height that may be different from the first height. In some cases, the plurality of conductive pillars 240 may include a first group of conductive pillars (e.g., two or more conductive pillars 240-a) having a first cross-sectional area and a second group of conductive pillars (e.g., two or more conductive pillars 240-b, two or more conductive pillars 240-c, two or more conductive pillars 240-d) having a second cross-sectional area that may be different from the first cross-sectional area. In some cases, the plurality of conductive pillars 240 may include groups of conductive pillars (e.g., four (4) groups of conductive pillars), each group of conductive pillars corresponding to a respective semiconductor die of the plurality (e.g., conductive pillars 240-a corresponding to semiconductor die 230-a, conductive pillars 240-b corresponding to semiconductor die 230-b, conductive pillars 240-c corresponding to semiconductor die 230-c, conductive pillars 240-d corresponding to semiconductor die 230-d). For example, two or more conductive pillars 240-a may provide interconnects to a semiconductor die 230-a, two or more conductive pillars 240-b may provide interconnects to a semiconductor die 230-b, and so on, and conductive pillars 240 that provide interconnects to a semiconductor die 230 may be referred to as corresponding to the semiconductor die 230. In some cases, such as in the example of FIG. 2A or any of other example in accordance with the concepts described herein, conductive pillars 240 corresponding to one semiconductor die 230 may have a same height, a same cross-sectional area, or both, and conductive pillars 240 corresponding to another semiconductor die 230 may have a different height, a different cross-sectional area, or both. In some such cases, conductive pillars 240 corresponding to the one semiconductor die 230 and to the another semiconductor die 230 may be impedance-matched to a common target impedance, pillar-wire combinations corresponding to the one semiconductor die 230 and to the another semiconductor die 230 may be impedance-matched to a common target impedance, or both.

In some cases, a combination of a bond wire of the plurality (e.g., a bond wire 250-a) and the corresponding conductive pillar (e.g., a conductive pillar 240-a) may form a pillar-wire combination. As such, a multi-die package of the diagram 201 may include a plurality of pillar-wire combinations where pillar-wire combinations in the plurality may each have a same impedance (e.g., 40 ohms). In some cases, the plurality of conductive pillars 240 may include conductive pillars that each individually may have a matched impedance (e.g., each conductive pillar in the plurality may be matched to a common impedance and thus may have a same pillar impedance). In other cases, the plurality of conductive pillars 240 may include conductive pillars that individually may have different impedances (e.g., a first conductive pillar may have a different pillar impedance than a second conductive pillar), but which when combined with a corresponding bond wire may provide a matched pillar-wire combination impedance.

In some cases, the plurality of pillar-wire combinations may include groups of pillar-wire combinations, where pillar-wire combinations in different groups of pillar-wire combinations may have different impedances (e.g., 20, 30, 40 ohms). Among the different groups of pillar-wire combinations, different groups may be configured to carry different types or categories of signals. For example, a first group of pillar-wire combinations may be configured to communicate a first category of signals (e.g., a power signal) and a second group of pillar-wire combinations may be configured to communicate a second category of signals (e.g., a clock signal, a data signal).

In some cases, the plurality of semiconductor dice 230 may include a stack of semiconductor dice (e.g., semiconductor dice stacked in y-direction) as depicted in the diagram 201. Further, a subset of the semiconductor dice 230 of the stack (e.g., a semiconductor die 230-a) may be offset in a first direction (e.g., x-direction). In some cases, a first semiconductor die of the plurality (e.g., a semiconductor die 230-a) may be offset relative to a second semiconductor die of the plurality (e.g., a semiconductor die 230-d) in the first direction (e.g., positive x-direction) and a third semiconductor die of the plurality (e.g., a semiconductor die 230-b) may be offset relative to the second semiconductor die of the plurality in a second direction that is opposite to the first direction (e.g., negative x-direction). In some cases, the subset of the semiconductor dice of the stack (e.g., a semiconductor die 230-a) may be further offset in a second direction that is orthogonal to the first direction (e.g., z-direction).

In some cases, a stack of semiconductor dice may include openings 260, which may also be referred to as gaps or recesses, between semiconductor dice that are separated by one or more other semiconductor dice of the stack. Such openings 260 may be based on a configuration of semiconductor dice stacking—e.g., if semiconductor dice of the stack are variously offset in one or more directions, an opening 260 may exist between one semiconductor die (e.g., a semiconductor die 230-c) and another semiconductor die (e.g., a semiconductor die 230-a), due to an intervening semiconductor die (e.g., a semiconductor die 230-b) being offset in at least one direction (e.g., the x direction). For example, a stack of semiconductor dice 230-a through 230-d depicted in the diagram 201 may include an opening (e.g., an opening 260) determined by a distance from a bond pad (e.g., a bond pad 225-b) of a lower semiconductor die (e.g., a semiconductor die 230-c) to a lower surface of an upper semiconductor die (e.g., a semiconductor die 230-a). The opening may be sufficient to have a bond wire formed on the bond pad (e.g., the bond pad 225-b) without bumping into the upper semiconductor die (e.g., the semiconductor die 230-a). In some cases, such opening (e.g., the opening 260) may be not be necessary based on a configuration of semiconductor dice stacking (e.g., a stack of semiconductor dice 230-e through 230-h illustrated in a diagram 202 of FIG. 2B).

FIG. 2B illustrates an exemplary diagram 202 of a multi-die package that supports interconnects for a multi-die package in accordance with aspects disclosed herein. The diagram 202 may include aspects of the computing system 100 described with reference to FIG. 1. The diagram 202 illustrates an example of a stack of semiconductor dice disposed above a substrate in a multi-die package and interconnects that may couple bond pads of the semiconductor dice with bond pads of the substrate. The diagram 202 may depict a cross-sectional view captured in a plane in the z-direction (e.g., a plane in the z-direction that includes x-axis and y-axis). As such, other structures (not shown) may exist in a different plane in the z-direction. The diagram 202 provides an illustrative example of various features in accordance with aspects disclosed herein, which are not limited to this example.

The diagram 202 illustrates components that may support the same or similar functions as the components described with reference to the diagram 201 in FIG. 2A—e.g., a set of solder balls 205 (e.g., a solder ball 205-b of the set of solder balls), a substrate 210-b, an encapsulant 215-b, a plurality of semiconductor dice 230 (e.g., semiconductor dice 230-e through semiconductor dice 230-h), a die attach film (DAF) (e.g., DAF 235-e), a plurality of conductive pillars 240 (e.g., conductive pillars 240-e through 240-h), a plurality of bond wires 250 (e.g., bond wires 250-e through 250-h). In some cases, the components illustrated in the diagram 202 may have the same or similar configurations as the corresponding components illustrated in the diagram 201.

In some cases, the plurality of semiconductor dice 230 may include a stack of semiconductor dice (e.g., semiconductor dice stacked in y-direction) as depicted in the diagram 202. In some cases, the plurality of conductive pillars (e.g., conductive pillars 240-e through 240-h) may be disposed above a first region of the substrate (e.g., the substrate 210-b) and the stack of semiconductor dice (e.g., semiconductor dice 230-e through 230-h) may be disposed above a second region of the substrate. Further, each semiconductor die of the stack (e.g., each semiconductor die 230-e, 230-f, or 230-g) may be disposed farther from the first region than any lower semiconductor die of the stack. In some cases, a subset of the semiconductor dice 230 of the stack (e.g., a semiconductor die 230-e) may be offset in a first direction (e.g., x-direction). In some cases, the subset of the semiconductor dice of the stack (e.g., a semiconductor die 230-e) may be further offset in a second direction that is orthogonal to the first direction (e.g., z-direction).

In some cases, a device (e.g., a device 120 described with reference to FIG. 1) may include a plurality of semiconductor dice 230 (e.g., semiconductor dice 230-a through 230-d, semiconductor dice 230-e through 230-h) disposed above a substrate (e.g., a substrate 210-a, a substrate 210-b), where each semiconductor die of the plurality (e.g., a semiconductor die 230-a, a semiconductor die 230-e) may include a bond pad of a plurality of bond pads (e.g., a bond pad 225-a, a bond pad 225-e). Further, the device may include a plurality of conductive pillars (e.g., conductive pillars 240-a through 240-d, conductive pillars 240-e through 240-h) disposed above the substrate, where a first group of conductive pillars of the plurality (e.g., two or more conductive pillars 240-d, two or more conductive pillars 240-h) may have a first height that may be less than a thickness of a semiconductor die of the plurality and a second group of conductive pillars of the plurality (e.g., two or more conductive pillars 240-a, two or more conductive pillars 240-e) may have a second height that is greater than the thickness of the semiconductor die.

The device may also include a plurality of bond wires (e.g., bond wires 250-a through 250-d, bond wires 250-e through 250-h) each electrically coupling a corresponding conductive pillar of the plurality (e.g., a conductive pillar 240-a, a conductive pillar 240-e) with a corresponding bond pad of the plurality (e.g., a bond pad 225-a, a bond pad 225-e). In some cases, the plurality of conductive pillars (e.g., conductive pillars 240-a through 240-d, conductive pillars 240-e through 240-h) may be impedance-matched to a common impedance (e.g., 40 ohms).

FIG. 3A and 3B illustrate exemplary diagrams 301 and 302 of multi-die packages that support interconnects for a multi-die package in accordance with aspects disclosed herein. The diagrams 301 and 302 each may include aspects of the computing system 100 described with reference to FIG. 1. The diagrams 301 and 302 each illustrate an example of a stack of semiconductor dice disposed above a substrate in a multi-die package and interconnects that may couple bond pads of the semiconductor dice with bond pads of the substrate. The diagrams 301 and 302 each may depict a cross-sectional view captured in a plane in the z-direction (e.g., a plane in the z-direction that includes x-axis and y-axis). As such, other structures (not shown) may exist in a different plane in the z-direction. The diagrams 301 and 302 provide illustrative examples of various features in accordance with aspects disclosed herein, which are not limited to these examples.

The diagrams 301 and 302 illustrate components that may support the same or similar functions as the components illustrated in the diagrams 201 and 202 as described with reference to FIG. 2A and FIG. 2B, such as a set of solder balls 305 (e.g., a solder ball 305-a of the set of solder balls of the diagram 301, a solder ball 305-b of the set of solder balls of the diagram 302), a substrate 310 (e.g., a substrate 310-a of the diagram 301, a substrate 310-b of the diagram 302), an encapsulant 315 (e.g., an encapsulant 315-a of the diagram 301, an encapsulant 315-b of the diagram 302), a plurality of semiconductor dice 330 (e.g., semiconductor dice 330-a through 330-d of the diagram 301, semiconductor dice 330-e through 330-h of the diagram 302), a die attach film (DAF) (e.g., a DAF 335-a of the diagram 301, a DAF 335-e of the diagram 302), a plurality of conductive pillars 340 (e.g., conductive pillars 340-a through 340-d of the diagram 301, conductive pillars 340-e through 340-h of the diagram 302), or a plurality of bond wires 350 (e.g., bond wires 350-a through 350-d of the diagram 301, bond wires 350-e through 350-h of the diagram 302). In some cases, the components illustrated in the diagrams 301 and 302 may have the same or similar configurations as the corresponding components illustrated in the diagrams 201 and 202.

In some cases, each conductive pillar of the plurality may have a substantially identical height as depicted in the diagrams 301 and 302, which may improve ease or cost of manufacturing. In some case, at least some of the plurality of conductive pillars (e.g., the conductive pillars 340-a through 340-d, the conductive pillars 340-e through 340-h) having the substantially identical height may have different cross-sectional areas.

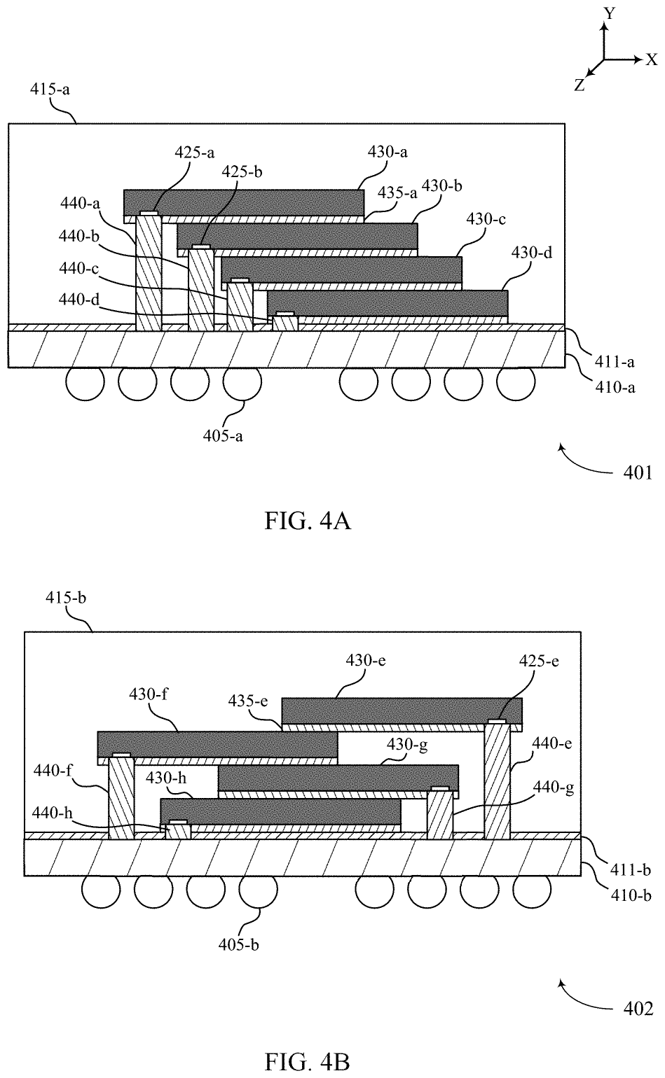

FIG. 4A illustrates an exemplary diagram 401 of a multi-die package that supports interconnects for a multi-die package in accordance with aspects disclosed herein. The diagram 401 may include aspects of the computing system 100 described with reference to FIG. 1. Further, the diagram 401 may include aspects of the diagrams 201 and 202 described with reference to FIGS. 2A and 2B. The diagram 401 illustrates an example of a stack of semiconductor dice disposed above a substrate in a multi-die package and interconnects that may couple bond pads of the semiconductor dice with bond pads of the substrate. The diagram 401 provides an illustrative example of various features in accordance with aspects disclosed herein, which are not limited to this example.

The diagram 401 illustrate a set of solder balls 405 (e.g., a solder ball 405-a of the set of solder balls). In some cases, the set of solder balls 405 are examples of the set of solder balls 205 described with reference to FIG. 2A. The diagram 401 also illustrate a substrate (e.g., a substrate 410-a), which may also be referred to as a package substrate. In some cases, the substrate 410-a is an example of the substrate 210-a described with reference to FIG. 2A. Further, the diagram 401 illustrates an encapsulant (e.g., an encapsulant 415-a) that may include a plurality of semiconductor dice 430 (e.g., semiconductor dice 430-a through 430-d) and a plurality of conductive pillars 440 (e.g., conductive pillars 440-a through 440-d). Further, the encapsulant 415-a may be an example of the encapsulant 215-a described with reference to FIG. 2A. Also, the plurality of semiconductor dice 430 and the plurality of conductive pillars 440 may be examples of the plurality of semiconductor dice 230 and the plurality of conductive pillars 240 described with reference to FIG. 2A.

Each semiconductor die of the plurality 430 (e.g., a semiconductor die 430-a) may include one or more bond pads (e.g., a bond pad 425-a). In some cases, a surface of a semiconductor die that is nearest the substrate 410-a may be referred to as a lower surface of the semiconductor die. In some cases, a lower surface of a semiconductor die (e.g., a semiconductor die 430-a) may include or otherwise be in contact with one or more bond pads (e.g., the bond pad 425-a). In some cases, a die attach film (DAF) (e.g., a DAF 435-a) may be disposed in contact with the lower surface of the semiconductor die (e.g., a semiconductor die 430-a). In some cases, the DAF 435-a is an example of the DAF 235-a described with reference to FIG. 2A. As such, the lower surface (e.g., the surface in contact with a bond pad 425-a) of each semiconductor die of the plurality 430 may face toward the substrate 410-a, which may be referred to as a flip-chip configuration in some cases. In some cases, a buffer layer 411-a may be disposed above a substrate (e.g., the substrate 410-a) to provide a space between a lowest semiconductor die of the stack (e.g., a semiconductor die 430-d) and the substrate (e.g., the substrate 410-a). The space may provide a room for disposing one or more conductive pillars (e.g., a conductive pillar 440-d) above the substrate (e.g., the substrate 410-a) or for otherwise providing connections to the lowest semiconductor die of the stack (e.g., a semiconductor die 430-d).

The diagram 401 illustrates that the plurality of conductive pillars 440 (e.g., conductive pillars 440-a through 440-d) may be disposed above the substrate 410-a, where each conductive pillar of the plurality (e.g., a conductive pillar 440-a) may be coupled with a corresponding substrate bond pad (and eventually to a host through a solder ball, e.g., a solder ball 405-a). In some cases, a plurality of semiconductor dice 430 (e.g., semiconductor dice 430-a through 430-d) may be disposed above a first region of a substrate (e.g., a substrate 410-a) and a plurality of conductive pillars 440 may be disposed above a second region of the substrate (e.g., the substrate 410-a). In some cases, the first region may include at least a portion of, if not all of, the second region.

In some cases, the plurality of conductive pillars 440 (e.g., conductive pillars 440-a through 440-d) may be impedance-matched to one another. In some cases, a first conductive pillar of the plurality (e.g., a conductive pillar 440-a) may have a different height than a second conductive pillar of the plurality (e.g., a conductive pillar 440-b). In some cases, a first conductive pillar of the plurality (e.g., a conductive pillar 440-a) may have a different cross-sectional area than a second conductive pillar of the plurality (e.g., a conductive pillar 440-b). For example, two conductive pillars 440 may have different heights but also different cross-sectional areas and thus be matched to a same impedance value.

In some cases, the plurality of conductive pillars 440 may further include groups of conductive pillars (e.g., two or more conductive pillars 440-a) and a height of conductive pillars (e.g., a conductive pillar 440-a) in a same group of conductive pillars (e.g., two or more conductive pillars 440-a) may correspond to a distance between the substrate and the lower surface of a corresponding semiconductor die of the plurality (e.g., a semiconductor die 430-a). In some cases, at least some, if not all, conductive pillars of the plurality (e.g., a conductive pillar 440-a) may be electrically coupled with the corresponding bond pad (e.g., a bond pad 425-a) via a solder. Additionally or alternatively, at least some, if not all, conductive pillars of the plurality (e.g., a conductive pillar 440-a) may be directly in contact with the corresponding bond pad (e.g., a bond pad 425-a).

In some cases, a conductive pillar (e.g., a conductive pillar 440-d) may have a height that may be less than a thickness of a semiconductor die (e.g., a semiconductor die 430-d). Another conductive pillar (e.g., a conductive pillar 440-a or a conductive pillar 440-c) may have a height that may be equal to (or substantially identical to) or greater than a thickness of a semiconductor die. Another conductive pillar (e.g., a conductive pillar 440-a or a conductive pillar 440-c) may have a height that may be equal to (or substantially identical to) or greater an integer multiple of a thickness of a semiconductor die.

FIG. 4B illustrates an exemplary diagram 402 of a multi-die package that supports interconnects for a multi-die package in accordance with aspects disclosed herein. The diagram 402 may include aspects of the computing system 100 described with reference to FIG. 1. The diagram 402 illustrates an example of a stack of semiconductor dice disposed above a substrate in a multi-die package and interconnects that may couple bond pads of the semiconductor dice with bond pads of the substrate. The diagram 402 may depict a cross-sectional view captured in a plane in the z-direction (e.g., a plane in the z-direction that includes x-axis and y-axis). As such, other structures (not shown) may exist in a different plane in the z-direction. The diagram 402 provides an illustrative example of various features in accordance with aspects disclosed herein, which are not limited to this example.

The diagram 402 illustrates components that may support the same or similar functions as the components described with reference to the diagram 401 in FIG. 4A—e.g., a set of solder balls 405 (e.g., a solder ball 405-b of the set of solder balls), a substrate 410-b, an encapsulant 415-b, a plurality of semiconductor dice 430 (e.g., semiconductor dice 430-e through semiconductor dice 430-h), a die attach film (DAF) (e.g., DAF 435-e), a plurality of conductive pillars 440 (e.g., conductive pillars 440-e through 440-h). In some cases, the components illustrated in the diagram 402 may have the same or similar configurations as the corresponding components illustrated in the diagram 401.

In some cases, a device (e.g., a device 120 described with reference to FIG. 1) may include a plurality of semiconductor dice 430 (e.g., semiconductor dice 430-a through 430-d, semiconductor dice 430-e through 430-h disposed above a first region of a substrate (e.g., a substrate 410-a, a substrate 410-b), where each semiconductor die of the plurality (e.g., a semiconductor die 430-a, a semiconductor die 430-e) may include a bond pad (e.g., a bond pad 425-a, a bond pad 425-e). The device may also include a plurality of conductive pillars (e.g., conductive pillars 440-a through 440-d, conductive pillars 440-e through 440-h) disposed above a second region of the substrate, the first region at least partially including the second region.

In some cases, each conductive pillar of a first group of conductive pillars of the plurality (e.g., two or more conductive pillars 440-a, two or more conductive pillars 440-e) may have a first height corresponding to a first distance between a first semiconductor die of the plurality (e.g., a semiconductor die 430-a, a semiconductor die 430-e) and the substrate (e.g., the substrate 410-a, the substrate 410-b). Further, each conductive pillar of a second group of conductive pillars of the plurality (e.g., two or more conductive pillars 440-c, two or more conductive pillars 440-g) may have a second height corresponding to a second distance between a second semiconductor die of the plurality (e.g., a semiconductor die 430-c, a semiconductor 430-g) and the substrate (e.g., the substrate 410-a, the substrate 410-b). In some cases, each conductive pillar (e.g., a conductive pillar 440-a, a conductive pillar 440-e) of the first group may be in contact with the first semiconductor die (e.g., the semiconductor die 430-a, the semiconductor die 430-e) and each conductive pillar (e.g., a conductive pillar 440-c, a conductive pillar 440-g) of the second group may be in contact with the second semiconductor die (e.g., the semiconductor die 430-c,the semiconductor die 430-g).

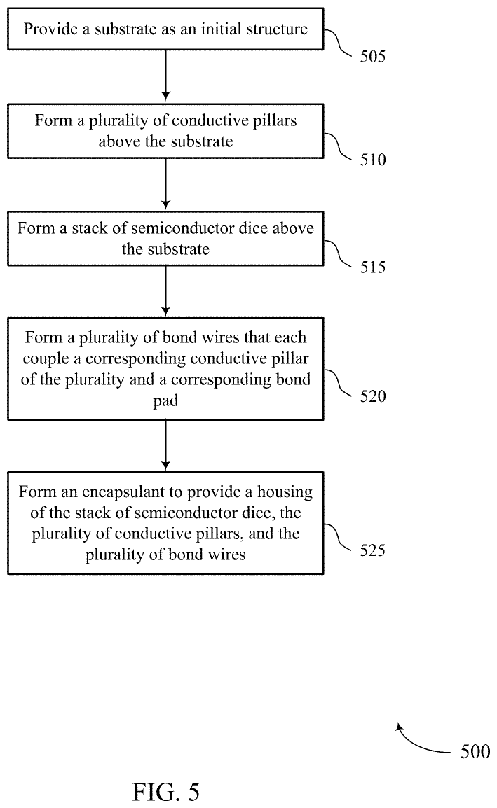

FIG. 5 shows a flowchart illustrating a method 500 that supports interconnects in a multi-die package in accordance with aspects disclosed herein. The method 500 may be or include aspects of a method of fabricating structures depicted in the diagram 201 or 202 of FIGS. 2A or 2B in accordance with the techniques described herein, which are not limited to these examples.

At 505 a substrate (e.g., a substrate 210-a with a set of solder balls 205 attached as described with reference to FIG. 2A) may be provided or identified as an initial structure. The substrate (e.g., the substrate 210-a) may also include a plurality of bond pads (which may also be referred to as a plurality of substrate bond pads). Each bond pad of the plurality (e.g., each substrate bond pad of the plurality) may be coupled with one or more solder balls 205 (e.g., a solder ball 205-a described with reference to FIG. 2A) through embedded conductive paths (e.g., traces or wires) preconfigured in the substrate (e.g., the substrate 210-a).

At 510 a plurality of conductive pillars (e.g., conductive pillars 240-a through 240-d of the diagram 201) may be formed above the substrate (e.g., the substrate 210-a). In some cases, a first sacrificial layer may be deposited above the substrate (e.g., the substrate 210-a). A thickness of the first sacrificial layer may correspond to a height of a first group of conductive pillars of the plurality (e.g., two or more conductive pillars 240-d of the diagram 201). Subsequently, the first sacrificial layer may be patterned to form a first group of holes in the first sacrificial layer. The first group of holes may correspond to a first group of conductive pillars of the plurality (e.g., two or more conductive pillars 240-d of the diagram 201). In some cases, the first group of holes may correspond to the plurality of substrate bond pads. The first group of holes may have various shapes (e.g., circular shapes having different areas) based on various impedances targets in some cases. Further, the first group of holes may be filled with one or more conductive materials (e.g., copper (Cu), tungsten (W) as described herein) that may form contacts with the first group of substrate bond pads of the plurality (or the plurality of substrate bond pads in some cases). In some cases, one or more liner layers (e.g., titanium (Ti), titanium nitrides (TiNₓ), tantalum (Ta), tantalum nitrides (TaNₓ), or some combination thereof) may be formed in the first group of holes before filling the first group of holes with the conductive materials.

Excessive conductive materials formed on the surface of the first sacrificial layer may be removed—e.g., by using a chemical-mechanical polish (CMP) process or an etch-back process—to expose conductive materials in the first group of holes. In this manner, a first group of conductive pillars may be formed, which may correspond to the first group of substrate bond pads of the plurality. In some cases, the first group of conductive pillars may be formed, which may correspond to the plurality of substrate bond pads, such that additional conductive pillars may thereafter be formed on top of (e.g., in contact with or otherwise coupled with) the first group of conductive pillars, where a conductive pillar in a first group and a conductive pillar formed on top thereof combine to collectively form a single conductive pillar. As such, a conductive pillar may have one or more portions with different shapes (e.g., different cross-sectional areas) or comprising different materials.

In some cases, a second sacrificial layer may be deposited after the excessive conductive materials on the surface of the first sacrificial layer have been removed. A sum of thicknesses of the first sacrificial layer and the second sacrificial layer may correspond to a height of second group of conductive pillars of the plurality. Subsequently, the second sacrificial layer may be patterned to form a second group of holes in the second sacrificial layer. In some cases, the second group of holes may extend down to a second group of substrate bond pads of the plurality through the first and the second sacrificial layers. In some cases (e.g., when the first group of holes correspond to the plurality of the substrate bond pads), the second group of holes may extend down to an exposed surface of the conductive pillars formed in the first group of holes. The second group of holes may be filled with one or more conductive materials and excessive conductive materials on top of the second sacrificial layer may be removed to form a second group of conductive pillars.

The process steps described herein may be repeated to form groups of conductive pillars of a plurality as necessary. After forming the plurality of conductive pillars, sacrificial layers deposited on top of the substrate 210 may be removed—e.g., using a selective etch process—to leave the plurality of conductive pillars.

At 515 a stack of semiconductor dice (e.g., semiconductor dice 230-a through 230-d of the diagram 201) may be disposed (e.g., placed or otherwise positioned) above the substrate (e.g., the substrate 210-a). In some cases, a DAF (e.g., a DAF 235-a of the diagram 201) may be disposed in contact with a lower surface of a semiconductor die (e.g., a surface exclusive of a bond pad of the semiconductor die). In some cases, the DAF may be applied to a lower surface of a semiconductor die 230 (e.g., a semiconductor die 230-a) before the semiconductor die 230 may be placed on top of an already-placed lower die 230 (e.g., a semiconductor die 230-b). In some cases, a stack of semiconductor dice (e.g., semiconductor dice 230-a through 230-d) may be formed (including the DAF disposed on a lower surface of each semiconductor die of the stack) before the stack of semiconductor dice may be disposed (e.g., placed or otherwise positioned) above the substrate (e.g., the substrate 210-a). As such, an upper surface (e.g., the surface in contact with a bond pad 225-a) of each semiconductor die of the stack may face away from the substrate.

At 520 a plurality of bond wires may be formed such that each bond wire (e.g., a bond wire 250-a) of the plurality may couple a corresponding conductive pillar (e.g., a conductive pillar 240-a) of the plurality and a corresponding bond pad (e.g., a bond pad 225-a) of a semiconductor die (e.g., a semiconductor die 230-a) of the stack.

At 525 an encapsulant (e.g., an encapsulant 215-a) may be formed to provide a housing for the stack of semiconductor dice (e.g., semiconductor dice 230-a through 230-d), the plurality of conductive pillars (e.g., conductive pillars 240-a through 240-d), and the plurality of bond wires (e.g., bond wires 250-a through 250-d). In some cases, the encapsulant (e.g., the encapsulant 215-a) may be or include a filler material (e.g., an epoxy compound) to provide a mechanical support for the stack of semiconductor dice, the plurality of conductive pillars, and the plurality of bond wires.

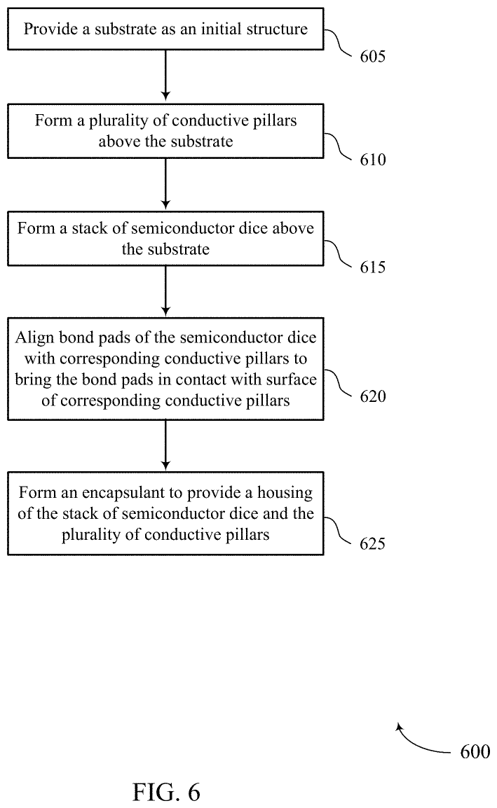

FIG. 6 shows a flowchart illustrating a method 600 that supports interconnects in a multi-die package in accordance with aspects disclosed herein. The method 600 may be or include aspects of a method of fabricating structures depicted in the diagram 401 or 402 of FIGS. 4A or 4B in accordance with the techniques described herein, which are not limited to these examples.

At 605 a substrate (e.g., a substrate 410-a with a set of solder balls 405 attached as described with reference to FIG. 4A) may be provided or identified as an initial structure. In some cases, the substrate (e.g., the substrate 410-a) may be an example of or include aspects of the substrate 210-a described with reference to FIG. 2A.

At 610 a plurality of conductive pillars (e.g., conductive pillars 440-a through 440-d of the diagram 401) may be formed above the substrate (e.g., the substrate 410-a) as described with reference to FIG. 5.

At 615 a stack of semiconductor dice (e.g., semiconductor dice 430-a through 430-d of the diagram 401) may be disposed (e.g., placed or otherwise positioned) above the substrate (e.g., the substrate 410-a). In some cases, a DAF (e.g., a DAF 435-a of the diagram 401) may be disposed in contact with a lower surface of a semiconductor die (e.g., a surface in contact with a bond pad of the semiconductor die). The DAF (e.g., the DAF 435-a) may be patterned to expose the bond pads (e.g., a bond pad 425-a) of the semiconductor die. In some cases, the DAF (e.g., the DAF 435-a) may be applied (and patterned to expose the bond pads 425-a) to a lower surface of a semiconductor die 430 (e.g., a semiconductor die 430-a) before the semiconductor die 430 may be placed on top of an already-placed lower die 430 (e.g., a semiconductor die 430-b). In other cases (not shown), the DAF (e.g., the DAF 435-a) may be applied to an upper surface (e.g., an opposite surface of a semiconductor die that is exclusive of bond pads) of an already-placed lower die 430 (e.g., a semiconductor die 430-b) before an upper semiconductor die 430 (e.g., a semiconductor die 430-a) may be placed on top of the DAF (e.g., the DAF 435-a) (thus, patterning the DAF may not be necessary). In some cases, a stack of semiconductor dice (e.g., semiconductor dice 430-a through 430-d) may be formed (including the DAF disposed between semiconductor dice of the stack) before the stack of semiconductor dice may be disposed (e.g., placed or otherwise positioned) above the substrate (e.g., the substrate 410-a). As such, the lower surface (e.g., the surface in contact with a bond pad 425-a) of each semiconductor die of the stack may face toward the substrate, which may be referred to as a flip-chip configuration in some cases.

At 620 the bond pads (e.g., a bond pad 425-a) of the semiconductor dice (e.g., a semiconductor die 430-a) may be aligned with corresponding conductive pillars (e.g., a conductive pillar 440-a). Further, the bond pads (e.g., the bond pads 425-a) of the semiconductor dice (e.g., the semiconductor die 430-a) may be in contact with surface of corresponding conductive pillars (e.g., conductive pillars 440-a). In some cases, a thermal process may be used to reduce a contact resistance between the bond pads (e.g., the bond pads 425-a) and the surface of corresponding conductive pillars (e.g., the conductive pillars 440-a). In some cases, a solder may be disposed on the bond pads of the semiconductor dice or on the surface of conductive pillars, or both, such that the solder may facilitate formation of a robust contact between the bond pads of the semiconductor dice and the surface of conductive pillars.

At 625 an encapsulant (e.g., an encapsulant 415-a) may be formed to provide a housing for the stack of semiconductor dice (e.g., semiconductor dice 430-a through 430-d) and the plurality of conductive pillars (e.g., conductive pillars 440-a through 440-d). In some cases, the encapsulant (e.g., the encapsulant 415-a) may be or include a filler material (e.g., an epoxy compound) to provide a mechanical support for the stack of semiconductor dice and the plurality of conductive pillars.

It should be noted that the methods described herein describe possible implementations, and that the operations and the steps may be rearranged or otherwise modified and that other implementations are possible. Further, examples from two or more of the methods may be combined.

Information and signals described herein may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof. Some drawings may illustrate signals as a single signal; however, it will be understood by a person of ordinary skill in the art that the signal may represent a bus of signals, where the bus may have a variety of bit widths.

The term “electronic communication” and “coupled” refer to a relationship between components that support electron flow between the components. This may include a direct connection between components or may include intermediate components. Components in electronic communication or coupled to one another may be actively exchanging electrons or signals (e.g., in an energized circuit) or may not be actively exchanging electrons or signals (e.g., in a de-energized circuit) but may be configured and operable to exchange electrons or signals upon a circuit being energized. By way of example, two components physically connected via a switch (e.g., a transistor) are in electronic communication or may be coupled regardless of the state of the switch (i.e., open or closed).

As used herein, the term “substantially” means that the modified characteristic (e.g., a verb or adjective modified by the term substantially) need not be absolute but is close enough so as to achieve the advantages of the characteristic.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, well-known structures and devices are shown in block diagram form in order to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

Information and signals described herein may be represented using any of a variety of different technologies and techniques. For example, data, instructions, commands, information, signals, bits, symbols, and chips that may be referenced throughout the herein description may be represented by voltages, currents, electromagnetic waves, magnetic fields or particles, optical fields or particles, or any combination thereof.

Also, as used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope disclosed herein. In other words, as used herein, the phrase “based on” shall be construed in the same manner as the phrase “based at least in part on.”

The description herein is provided to enable a person skilled in the art to make or use the disclosure. Various modifications to the disclosure will be readily apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. An apparatus, comprising:
a plurality of semiconductor dice disposed above a substrate, each semiconductor die of the plurality comprising an upper surface in contact with a bond pad;
a plurality of conductive pillars above the substrate; and
a plurality of bond wires each coupled with a corresponding conductive pillar of the plurality and a corresponding bond pad.

2. The apparatus of claim 1, wherein:
the plurality of bond wires and the plurality of conductive pillars comprise a plurality of pillar-wire combinations that each comprise a bond wire of the plurality and the corresponding conductive pillar, and
the pillar-wire combinations of the plurality each have a matched impedance.

3. The apparatus of claim 2, wherein the plurality of conductive pillars comprises:
conductive pillars that each have a matched impedance.

4. The apparatus of claim 2, wherein the plurality of conductive pillars comprises:
a first conductive pillar of the plurality that has a different impedance than a second conductive pillar of the plurality.

5. The apparatus of claim 1, wherein:
a conductive pillar of the plurality has a height that is greater than or equal to a thickness of a semiconductor die of the plurality.

6. The apparatus of claim 1, wherein the plurality of conductive pillars comprises:
a first group of conductive pillars having a first height and a second group of conductive pillars having a second height different from the first height.

7. The apparatus of claim 1, wherein the plurality of conductive pillars comprises:
a first group of conductive pillars having a first cross-sectional area and a second group of conductive pillars having a second cross-sectional area different from the first cross-sectional area.

8. The apparatus of claim 1, wherein the plurality of conductive pillars comprises:
groups of conductive pillars, each group of conductive pillars corresponding to a respective semiconductor die of the plurality.

9. The apparatus of claim 1, wherein:
the plurality of bond wires and the plurality of conductive pillars comprise a plurality of pillar-wire combinations that each comprise a bond wire of the plurality and the corresponding conductive pillar; and
the plurality of pillar-wire combinations comprises groups of pillar-wire combinations, pillar-wire combinations in different groups of pillar-wire combinations having different impedances.

10. The apparatus of claim 9, wherein:
a first group of pillar-wire combinations is configured to communicate a first category of signals and a second group of pillar-wire combinations is configured to communicate a second category of signals.

11. The apparatus of claim 10, wherein:
the first category of signals comprises a power signal and the second category of signals comprises a clock signal or a data signal.

12. The apparatus of claim 1, wherein:
the plurality of semiconductor dice comprises a stack of semiconductor dice; and
a subset of the semiconductor dice of the stack are offset in a first direction.

13. The apparatus of claim 12, wherein:
a first semiconductor die of the plurality is offset relative to a second semiconductor die of the plurality in the first direction; and
a third semiconductor die of the plurality is offset relative to the second semiconductor die of the plurality in a second direction that is opposite to the first direction.

14. The apparatus of claim 12, wherein:
the subset of the semiconductor dice of the stack are offset in a second direction that is orthogonal to the first direction.

15. The apparatus of claim 12, wherein:
the plurality of conductive pillars is disposed above a first region of the substrate;
the stack of semiconductor dice is disposed above a second region of the substrate; and
each semiconductor die of the stack is disposed farther from the first region than any lower semiconductor die of the stack.

16. An apparatus, comprising:
a plurality of semiconductor dice disposed above a first region of a substrate, each semiconductor die of the plurality comprising a lower surface in contact with a bond pad; and
a plurality of conductive pillars above a second region of the substrate, the second region being subset of the first region, each conductive pillar of the plurality directly coupled with a corresponding bond pad.

17. The apparatus of claim 16, wherein conductive pillars of the plurality are impedance-matched to one another.

18. The apparatus of claim 17, wherein:
a first conductive pillar of the plurality has a different height than a second conductive pillar of the plurality.

19. The apparatus of claim 17, wherein:
a first conductive pillar of the plurality has a different cross-sectional area than a second conductive pillar of the plurality.

20. The apparatus of claim 16, wherein:
the plurality of conductive pillars further comprises groups of conductive pillars; and
a height of conductive pillars in a same group of conductive pillars corresponds to a distance between the substrate and the lower surface of a corresponding semiconductor die of the plurality.

21. The apparatus of claim 16, wherein:
each conductive pillar of the plurality is electrically coupled with the corresponding bond pad via a solder.

22. An apparatus, comprising:
a plurality of semiconductor dice disposed above a substrate, each semiconductor die of the plurality comprising a bond pad of a plurality of bond pads;
a plurality of conductive pillars disposed above the substrate, wherein a first group of conductive pillars of the plurality has a first height that is less than a thickness of a semiconductor die of the plurality and a second group of conductive pillars of the plurality has a second height that is greater than the thickness of the semiconductor die; and
a plurality of bond wires each electrically coupling a corresponding conductive pillar of the plurality with a corresponding bond pad of the plurality.

23. The apparatus of claim 16, wherein:
conductive pillars of the plurality are impedance-matched to a common impedance.

24. An apparatus, comprising:
a plurality of semiconductor dice disposed above a first region of a substrate, each semiconductor die of the plurality comprising a bond pad; and
a plurality of conductive pillars disposed above a second region of the substrate, the first region at least partially including the second region, wherein:
each conductive pillar of a first group of conductive pillars of the plurality has a first height corresponding to a first distance between a first semiconductor die of the plurality and the substrate; and
each conductive pillar of a second group of conductive pillars of the plurality has a second height corresponding to a second distance between a second semiconductor die of the plurality and the substrate.

25. The apparatus of claim 16, wherein:
each conductive pillar of the first group is in contact with the first semiconductor die; and
each conductive pillar of the second group is in contact with the second semiconductor die.
